(19) United States
(12) Patent Application Publication
(10) Pub. No.: US 2011/0068810 A1
(43) Pub. Date: Mar. 24, 2011

(54) SENSING METHOD AND DRIVING CIRCUIT OF CAPACITIVE TOUCH SCREEN

(75) Inventors: David Julian Yeates, NG Eys (NL); Frans Verweg, Heerlen (NL)

(73) Assignee: TPO Displays Corp., Chu-Nan (TW)

(21) Appl. No.: 12/725,421

(22) Filed: Mar. 16, 2010

Related U.S. Application Data
(60) Provisional application No. 61/166,700, filed on Apr. 3, 2009.

(51) Int. Cl. G01R 27/26

(52) U.S. Cl. 324/676

(57) ABSTRACT

In a sensing method of a capacitive touch screen, which includes a plurality of sensing capacitors, at least one of the plurality of sensing capacitors is selected into a reference capacitor unit. The capacitance differences between the reference capacitor unit and the sensing capacitors are calculated. A touched position on the capacitive touch screen is determined according to the capacitance differences.

### CROSS REFERENCE TO RELATED PATENT APPLICATION

This patent application is based on a U.S. provisional patent application No. 61/166,700 filed Apr. 3, 2009.

### FIELD OF THE INVENTION

The present invention relates to a capacitive touch screen, and more particularly to a sensing method of a capacitive touch screen, and also to a driving method of a capacitive touch screen.

### BACKGROUND OF THE INVENTION

Touch screens have been widely applied to a variety of portable electronic devices due to the features of easy manipulation and matured development. Among the commercially available touch screens, resistive touch sensors and capacitive touch sensors are currently the most popular to be used in touch screens for manipulation detection. Capacitive touch sensors are particularly popular and commercially talent in the art for being capable of supporting multi-touch techniques.

A capacitive touch sensor principally detects a change in capacitance resulting from electrostatic interaction between an electrode and a part of a human body approaching or touching the electrode, e.g. a finger. For implementing such detection means, a variety of capacitive touch sensor solutions are developed to acquire precise capacitive changes.

Please refer to FIG. 1 which schematically illustrates a capacitive touch sensing circuit according to prior art. As shown, the sensing circuit includes a capacitive switch set 10, a sigma-delta modulator 11, a modulator bitstream filter 13, a clock generator 14 and a firmware 15. The clock generator 14 generates a clock signal which is referred to for on/off control of switches Sw1 and Sw2 included in the capacitive switch set 10. The capacitive switch set 10 further includes a sensing capacitor Cs. When the switch Sw1 is in an open-circuit state and the switch Sw2 is in a conducting state, the sensing capacitor Cs charges the integrating capacitor Cint of the sigma-delta modulator 11. An output voltage of a comparator 111 included in the sigma-delta modulator 11 is switched to a high level as soon as the integrating capacitor Cint is charged to a level of the reference voltage signal Vref, wherein the time required for charging the integrating capacitor Cint up to the reference level is linearly dependent on the capacitance of the sensing capacitor Cs. Furthermore, the output voltage of the comparator 11 is latched by a latch 112 and used as a gating signal to control the enabling of a counter 130 included in the modulator bitstream filter 13. Therefore, the capacitance of the sensing capacitor Cs will be able to be estimated by a decision logic unit 150 included in the firmware 15 as it correlates to the counted value outputted by the counter 130.

The above mentioned prior art has a number of disadvantages. For example, charging of the integrating capacitor Cint involves many charge/discharge cycles of the sensing capacitor which consumes power and time. In addition, one integrating capacitor Cint is required for each sensing circuit. A parallel architecture using such a technique would therefore require many integrating capacitors which either requires a great deal of area in the chip or many external components. If a sequential architecture is adopted for measuring the capacitance of many sensors, noise would be an issue and sufficient filtering and shielding needs to be implemented.

### SUMMARY OF THE INVENTION

Therefore, the present invention provides a sensing method of a capacitive touch screen with reduced noise.

The present invention also provides a driving circuit of a capacitive touch screen, capable of implementing a sensing method of a capacitive touch screen to reduce noise.

In an aspect of the present invention, a sensing method of a capacitive touch screen, which includes a plurality of sensing capacitors, comprises steps of: selecting at least one of the plurality of sensing capacitors into a reference capacitor unit; calculating capacitance differences between the reference capacitor unit and other sensing capacitors; and locating a touched position on the capacitive touch screen according to the capacitance differences.

In another aspect of the present invention, a driving circuit of a capacitive touch screen for implementing differential capacitance measurement, which includes a reference capacitor unit with a reference capacitance and a plurality of sensing capacitors, comprises: a reference signal generator coupled to the reference capacitor unit and generating a pair of complementary reference voltage signals according to the reference capacitance; a plurality of sensing circuits coupled to the plurality of sensing capacitors and the reference signal generator, and receiving the pair of complementary reference voltage signals for measuring capacitance differences between the reference capacitor unit and the plurality of sensing capacitors; and a positioning circuit coupled to the sensing circuits for locating a touched position on the capacitive touch screen according to the measured capacitance differences.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a functional block diagram schematically illustrating a capacitive touch sensing circuit according to prior art;

FIG. 2A˜FIG. 2C are schematic diagrams illustrating an example of a touch screen layout where the present invention can be applied to, wherein FIG. 2A illustrates the use of a central sensing capacitor as the single reference capacitor; FIG. 2B illustrates the use of an external capacitor as the single reference capacitor; and FIG. 2C illustrates the use of multiple references.

FIG. 3 is a functional block diagram schematically illustrating a driving circuit of a capacitive touch screen for implementing differential capacitance measurement according to an embodiment of the present invention;

FIG. 4 is a circuit diagram illustrating an example of differential capacitance measuring means for use with the driving circuit of FIG. 3; and

FIG. 5 is a functional block diagram schematically illustrating a driving circuit of a capacitive touch screen for implementing differential capacitance measurement according to another embodiment of the present invention.

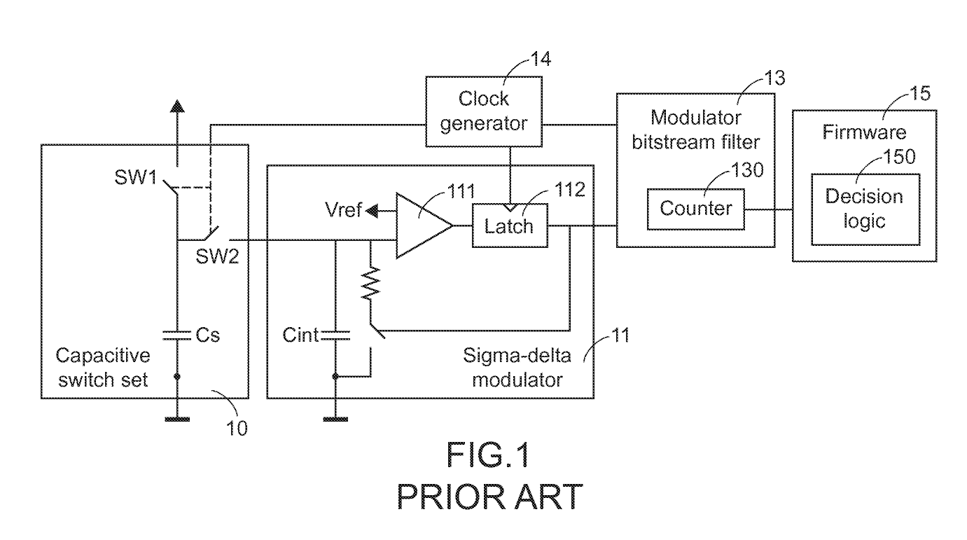

### DETAILED DESCRIPTION OF THE PREFERRED EMBODIMENT

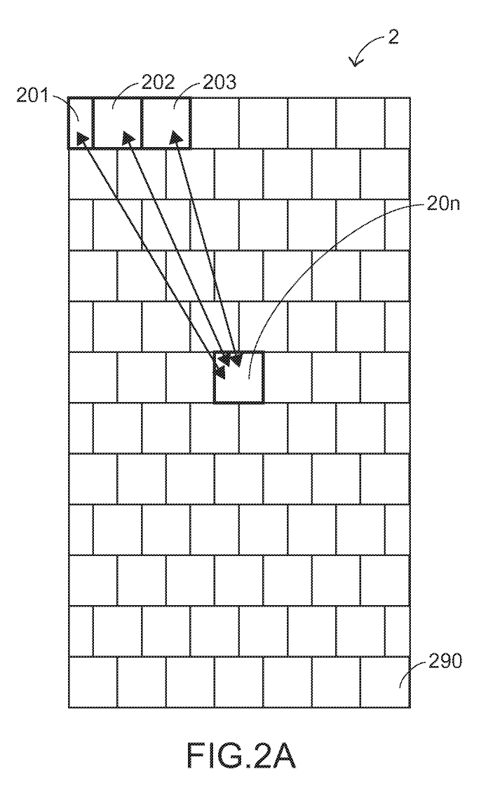

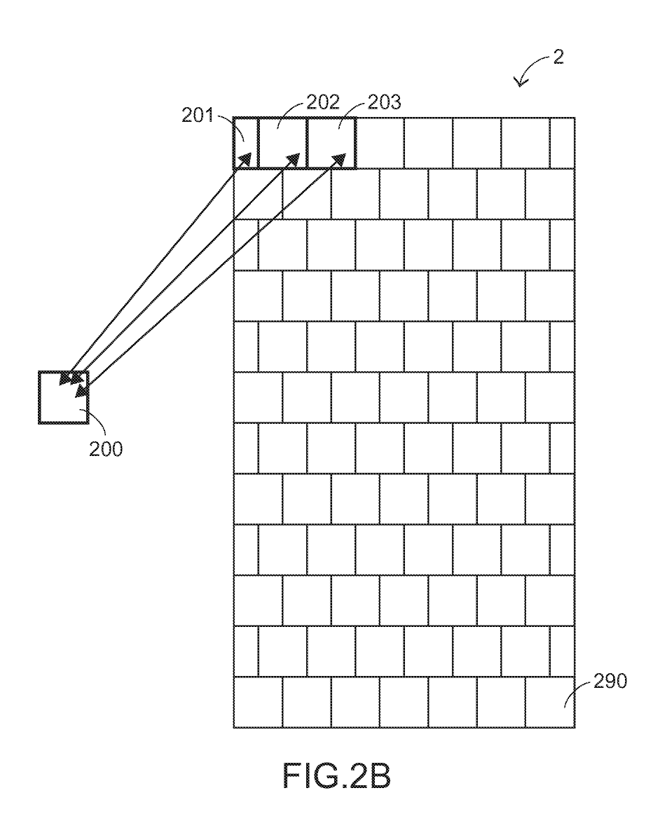

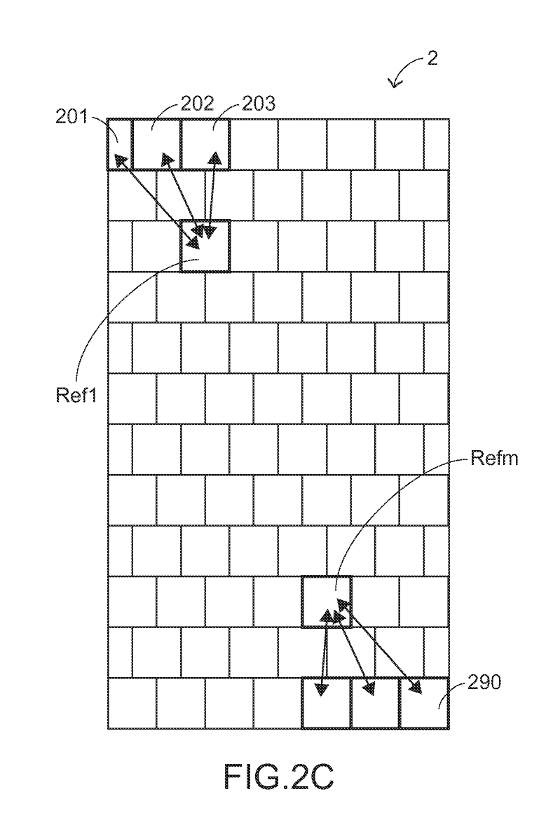

Please refer to FIG. 2A, which schematically illustrates an example of a touch screen layout where the present invention can be applied to. In this example, the touch screen 2 is disposed with 90 separate sensing capacitors 201˜290, in spite the number of the sensing capacitors can be selected depending on practical needs. According to the present invention, one of the sensing capacitors 201˜290 is selected into a reference capacitor unit to be a reference sensor and the capacitance of the reference sensor is used as a reference capacitance. Then differences between the reference capacitance and each of the other capacitances are calculated. By comparing the differences, the touched position by the user can be identified.

Principally, any of the sensing capacitors can be used as the reference. In an embodiment of the present invention, the central one 20n is selected as the reference sensor and subjected to a subtracting operation with the other sensing capacitors 201˜290. Alternatively, different reference sensors can be chosen in rotation for an averaging effect.

In another embodiment, an external capacitor 200 can be selected into a reference capacitor unit as a reference sensor, as illustrated in FIG. 2B, and differences between the external reference capacitance 200 and each of the sensing capacitances 201˜290 in the panel are calculated. By comparing the differences, the touched position by the user can be identified.

In a further embodiment, differential measurements are confined to a smaller area, and multiple sensing capacitors are selected into a reference capacitor unit. The sensing capacitances 201˜290 are divided into groups and multiple references Refl˜Refm are used in different groups for respective subtracting operations, as illustrated in FIG. 2C. By comparing the differences, the touched position by the user can be identified.

In still another embodiment, all the sensing capacitors are selected into a reference capacitor unit, and the average capacitance of all sensing capacitors 201˜290 are used as the reference capacitance to be compared with the sensing capacitances 201˜290. Differences between the reference capacitance and each of the sensing capacitances 201˜290 are calculated. By comparing the differences, the touched position by the user can be identified.

By the differential method according to the present invention, changes in capacitance of one sensor relative to another are detected. The differential method of touch sensing may lend itself to parallel measurement of all sensors. This reduces the problem of noise because the noise is correlated. Speed of touch detection can be increased because potentially less filtering will be required. Also, because a measurement can be done with a single charge/discharge cycle of each sensor compared with multiple cycles as used by other techniques power consumption can be reduced. Furthermore, in conventional touch screens the detection circuit(s) of the sensors often need to be calibrated to allow for varying measurement conditions. Due to the present method using differential techniques the problem of calibration is simplified because many changes in measurement conditions are the same for all sensors.

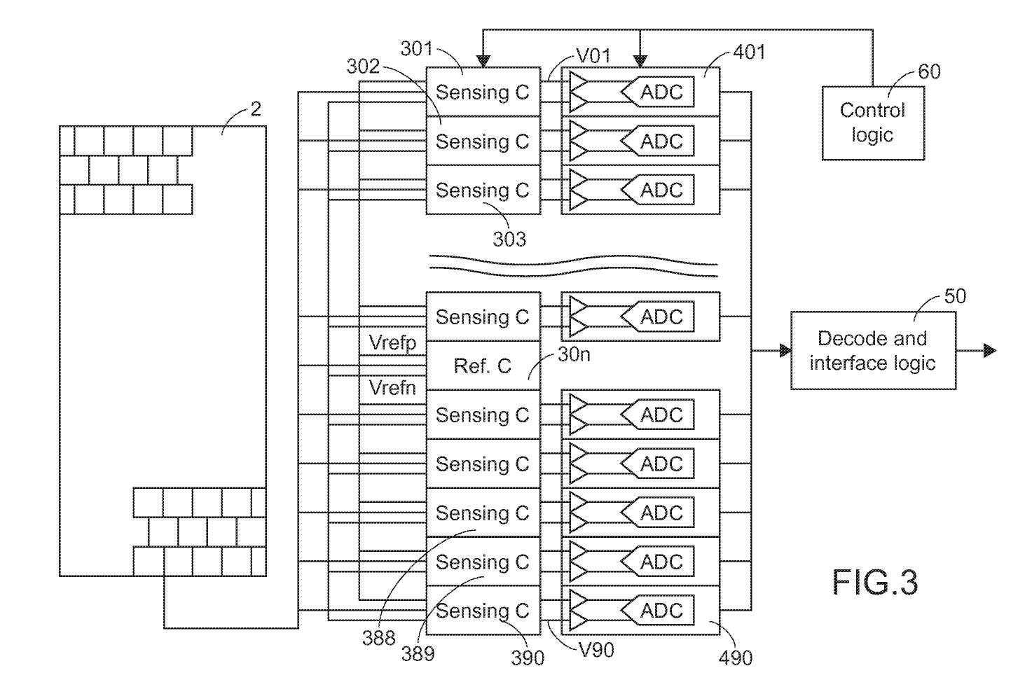

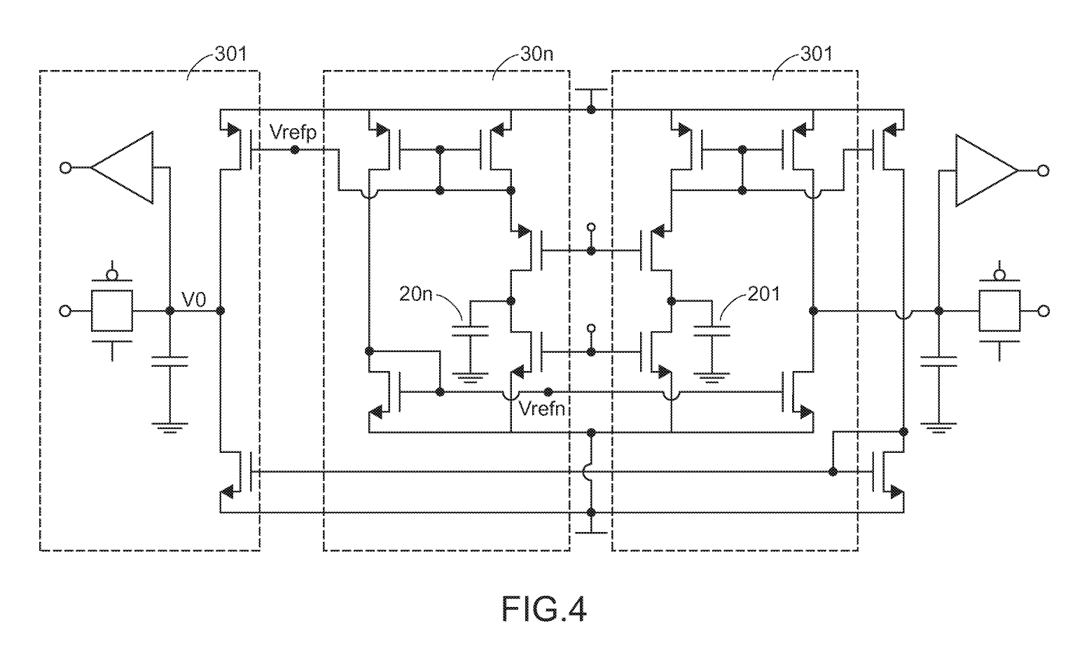

Hereinafter, a driving circuit of a capacitive touch screen for implementing the above-described differential capacitance measurements according to an embodiment of the present invention is illustrated with reference FIG. 3. The driving circuit includes a reference signal generator 30n and a plurality of identical sensing circuits 301˜390. The reference signal generator 30n is coupled to the reference sensing capacitor 20n as shown in FIG. 2A while the sensing circuits 301˜390 are coupled to the sensing capacitors 201˜290, respectively. The reference signal generator 30n generates a pair of complementary reference voltage signals Vrefp and Vrefn according to the reference capacitance for driving the differential capacitance measurements with the sensing circuits 301˜390. An example of the differential capacitance measurement is illustrated in FIG. 4, in which the coupling of the sensing circuit 301 to the reference signal generator 30n is shown, and may refer to Prakash & Abshire, “A Fully Differential Rail-to-Rail Capacitance Measurement Circuit for Integrated Cell Sensing”, IEEE SENSORS 2007 Conference, p. 1444-1447, which is incorporated herein for reference.

The capacitance differences between the reference sensing capacitor 20n and each of the sensing capacitors 201˜290 are thus realized as analog output voltages V01˜V90 excluding Vn corresponding to the reference signal generator 30n. With the operational timing control by a control logic unit 60 coupled to the reference signal generator 30n and the sensing circuits 301˜390, the output voltages V01˜V90 are converted into digital data by corresponding analog-to-digital converters 401˜490 which serve as a positioning circuit. The digital data are then inputted to a decode and interface logic unit 50, to be processed, thereby realizing the touched position.

It is to be noted that the embodiment illustrated with reference to FIG. 3 is exemplified to be used with the reference setting illustrated in FIG. 2A. Similar circuitry can also be applied to other reference settings to accomplish differential capacitance measurement, which is understood by those skilled in the art. For example, an additional reference capacitor is provided in the embodiment of FIG. 2C, and then an additional reference signal generator is included in the driving circuit.

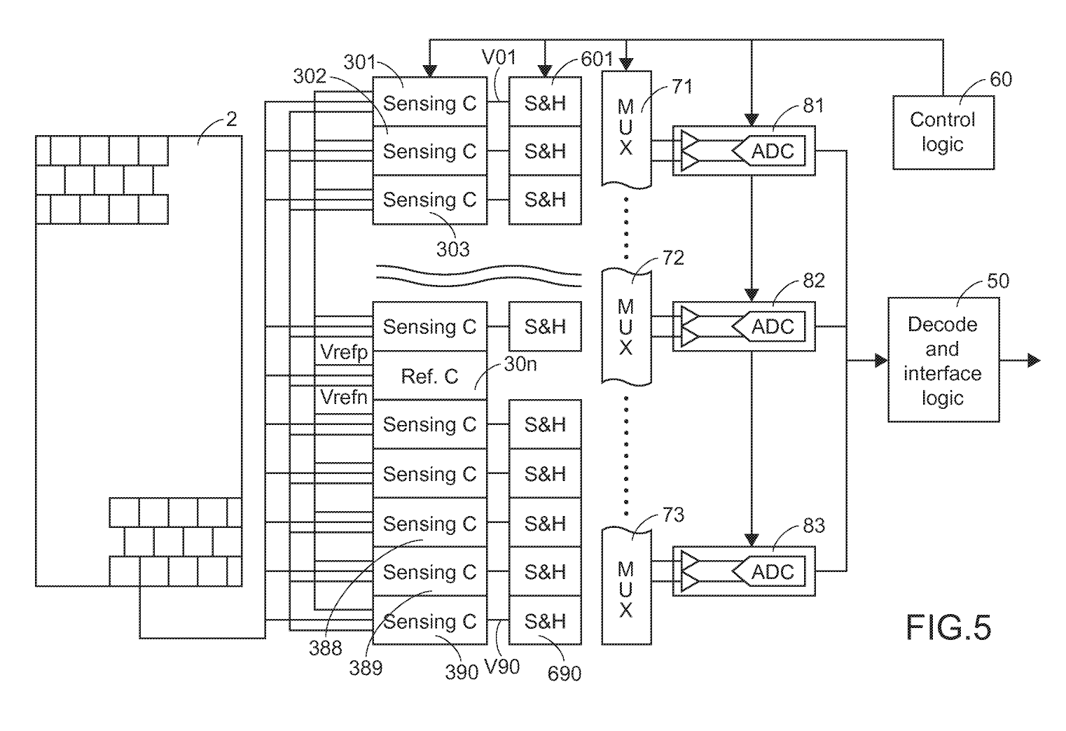

FIG. 5 illustrates a driving circuit of a capacitive touch screen for implementing differential capacitance measurements according to another embodiment of the present invention. In this embodiment, less analog-to-digital converters are used by grouping the sensing circuits. For example, the sensing circuits 301˜390 are divided into three groups so that only three analog-to-digital converters 81˜83 are required. For such implementation, the analog output voltages V01˜V90 outputted by the sensing circuits 301˜390, as described with reference to FIG. 3, are sampled and held for a specified period of time by corresponding sampling and holding units 601˜690, and then sequentially selected through multiplexers 71˜73. It is advantageous in simplification of circuitry.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A sensing method of a capacitive touch screen, the capacitive touch screen including a plurality of sensing capacitors, and the method comprising steps of:
selecting at least one of the plurality of sensing capacitors into a reference capacitor unit;
calculating capacitance differences between the reference capacitor unit and the sensing capacitors; and
locating a touched position on the capacitive touch screen according to the capacitance differences.

2. The sensing method according to claim 1 wherein one of the plurality of sensing capacitors is selected into the reference capacitor unit as a single reference capacitor.

3. The sensing method according to claim 1 wherein a central one of the plurality of sensing capacitors is selected into the reference capacitor unit as a single reference capacitor.

4. The sensing method according to claim 1 wherein different ones of the plurality of sensing capacitors are selected in rotation into the reference capacitor unit as a single reference capacitor.

5. The sensing method according to claim 1 wherein more than one of the plurality of sensing capacitors are selected into the reference capacitor unit as multiple reference capacitors, and average capacitance of the selected sensing capacitors is used as reference capacitance to calculate the capacitance differences.

6. The sensing method according to claim 1 wherein all the plurality of sensing capacitors are selected into the reference capacitor unit as multiple reference capacitors, and average capacitance of all the plurality of sensing capacitors is used as reference capacitance to calculate the capacitance differences.

7. The sensing method according to claim 1 further comprising steps of:
dividing the plurality of sensing capacitors into groups;
selecting one of the sensing capacitors in each group into the reference capacitor unit as a reference capacitor; and
calculating capacitance differences between the reference capacitor and the sensing capacitors in the same group for each group.

8. A driving circuit of a capacitive touch screen for implementing differential capacitance measurement, the capacitive touch screen including a reference capacitor unit with a reference capacitance and a plurality of sensing capacitors, and the driving circuit comprising:
a reference signal generator coupled to the reference capacitor unit and generating a pair of complementary reference voltage signals according to the reference capacitance;
a plurality of sensing circuits coupled to the plurality of sensing capacitors and the reference signal generator, and receiving the pair of complementary reference voltage signals for measuring capacitance differences between the reference capacitor and the plurality of sensing capacitors; and
a positioning circuit coupled to the sensing circuits for locating a touched position on the capacitive touch screen according to the measured capacitance differences.

9. The driving circuit according to claim 8 further comprising an additional reference signal generator if the capacitive touch screen includes an additional reference capacitor unit.

10. The driving circuit according to claim 8 wherein the measured capacitance differences are outputted by the sensing circuits as analog data, and the positioning circuit includes a plurality of analog-to-digital converters coupled to the sensing circuits for converting the analog data into digital data.

11. The driving circuit according to claim 10 wherein a number of the analog-to-digital converters is equal to a number of the sensing circuits.

12. The driving circuit according to claim 10 wherein the positioning circuit includes a control logic unit coupled to the sensing circuits and the analog-to-digital converters for operational timing control.

13. The driving circuit according to claim 10 wherein the positioning circuit includes a decode and interface logic unit coupled to the analog-to-digital converters for decoding the digital data and locating the touched position on the capacitive touch screen according to the digital data.

14. The driving circuit according to claim 10 wherein a number of the analog-to-digital converters is less than a number of the sensing circuits.

15. The driving circuit according to claim 14 wherein the positioning circuit includes:
a plurality of sampling and holding units coupled to the plurality of sensing circuits, respectively, for sampling and holding the analog data for a period of time; and
a plurality of multiplexers coupled to the analog-to-digital converters, respectively, each of which is further coupled to more than one of the sampling and holding units for sequentially selecting one of the sampled and held analog data to be outputted to the corresponding analog-to-digital converter.
